(19) United States
(12) Patent Application Publication
(10) Pub. No.: US 2026/0266900 A1
(43) Pub. Date: Sep. 10, 2026

(54) SCAN-BASED TEST CIRCUITRY FOR STRUCTURAL TESTING OF ANALOG AND MIXED-SIGNAL CIRCUITS

(71) Applicant: Siemens Industry Software Inc., Plano, TX (US)

(72) Inventor: Stephen Kenneth Sunter, Nepean (CA)

(73) Assignee: Siemens Industry Software Inc., Plano, TX (US)

(21) Appl. No.: 18/869,336

(22) PCT Filed: Jun. 8, 2022
(86) PCT No.: PCT/US2022/072818

§ 371 Date: Nov. 26, 2024

(51) Int. Cl. G01R 31/3163; G01R 31/3167

(52) U.S. Cl. CPC G01R 31/3163; G01R 31/3167

(57) ABSTRACT

A test circuit configured to test a circuit being at least partially analog, comprising: one or more scan chains and one or more threshold-comparing convertors. Each of the one or more thresholdcomparing convertors, comprising one or more threshold-comparing sub-convertors for one or more preset thresholds, is coupled to a selected node of the circuit, and wherein each of the one or more threshold-comparing sub-convertors is configured to output, based on comparing a voltage value at the selected node with one of the one or more preset thresholds, a bit value of the test response to a scan cell of the one or more scan chains. The test circuit may further comprise one or more node-connecting devices with inputs coupled to the one or more scan chains and with outputs coupled to one or more selected internal nodes of the circuit.

### FIELD OF THE DISCLOSED TECHNIQUES

The presently disclosed techniques relate to the field of testing analog and mixed-signal circuits. Various implementations of the disclosed techniques may be particularly useful for inserting test circuitry into circuit designs.

### BACKGROUND OF THE DISCLOSED TECHNIQUES

Integrated circuits are used in a wide range of applications such as consumer electronics, automotive, telecom, cloud computing, and artificial intelligence. While digital circuitry forms the core of most electronic systems today, these electronic systems are increasingly mixed-signal designs, embedding on a single die analog or mixed-signal blocks together with digital circuitry such as processors, logic blocks and memory blocks. Here, a mixed-signal block is a circuit block comprising both analog and digital circuitry.

The fabrication of integrated circuits comprises a series of photolithographic, printing, etching, implanting, and chemical vapor deposition steps. This process is subject to imperfections and can cause manufacture defects. The ever-continuing reduction in feature size further increases the probability of defective circuits. A very small defect may result in a faulty transistor or interconnecting wire. Even a single faulty transistor or wire can cause the entire chip to function improperly. It is thus necessary to test chips during the manufacturing process. Diagnosing faulty chips is also needed to ramp up and to maintain the manufacturing yield.

Testing typically includes applying a set of test stimuli (test patterns) to the circuit-under-test and then analyzing responses generated by the circuit-under-test. Functional testing attempts to validate that the circuit-under-test operates according to its functional specification. By contrast, structural testing tries to ascertain that the circuit-under-test has been assembled correctly from some low-level building blocks as specified in a structural netlist and these low-level building blocks and their wiring connections have been manufactured without defects. For structural testing, it is assumed that if functional verification performed during the design phase has shown the correctness of the netlist and structural testing during the manufacture phase has confirmed the correct assembly of the structural circuit elements, then the circuit should function correctly.

Structural testing has been widely adopted for testing digital circuits for the past several decades. One major advantage of structural testing is that it enables the test generation (test pattern generation) to focus on testing a limited number of relatively simple circuit elements rather than having to deal with an exponentially exploding multiplicity of functional states and state transitions. The current practice for testing analog and mixed-signal circuits, however, is still functional testing, also referred to as specification-based testing. Due to the nature of analog signals that are continuously changeable and various kinds of circuits for processing them, it is much more challenging to find a simple and universal mechanism to activate analog faults or defects and to capture test responses that require no complex analysis.

Despite the ease of interpreting the test result, specification-based testing relies on specialized automatic test equipment (ATE) with advanced capabilities and running the tests can take a long time. Moreover, specification-based testing can be very time-consuming to simulate because the complete end-to-end function is tested. Test generation automation has been developed only for very common and generic functions, like those of analog-to-digital converters (ADCs), digital-to-analog converters (DACs), phase-locked loops (PLLs), serializer/deserializer (SerDes), and voltage regulators. This relies on using stimuli and transfer function analysis that are specific to the generic function. No general method has been developed to generate tests for every type of circuit, especially for random analog circuitry.

Analog defect simulation, typically used to determine defect coverage of a test set, is also time-consuming. Unlike the often-used digital circuit fault model defined as a circuit node stuck at logic 0 or 1, modeling a short defect in an analog circuit typically comprises adding a 1-to-100 ohm resistor between two circuit nodes and modeling an open defect in an analog circuit typically comprises inserting a 0.1-to-10 Gohm resistor in a connection between two transistors. Each potential defect is simulated one at a time, and each such analog simulation can take minutes to days. With conventional technologies, the test equipment cost, test generation time, and test execution time have been and will continue to be impacted.

### BRIEF SUMMARY OF THE DISCLOSED TECHNIQUES

Various aspects of the disclosed technology relate to scan-based test circuitry for structural testing of analog and mixed-signal circuits. In one aspect, there is a test circuit configured to test a circuit being at least partially analog, comprising: one or more scan chains configured to shift test patterns generated for structural testing of the circuit into the circuit, to apply each of the test patterns to the circuit separately, and to capture a test response of the circuit for each of the test patterns; and one or more threshold-comparing convertors, wherein each of the one or more threshold-comparing convertors, comprising one or more threshold-comparing sub-convertors for one or more preset thresholds, is coupled to a selected node of the circuit, and wherein each of the one or more threshold-comparing sub-convertors is configured to output, based on comparing a voltage value at the selected node with one of the one or more preset thresholds, a bit value of the test response to a scan cell of the one or more scan chains.

The circuit may further comprise: one or more node-connecting devices with inputs coupled to the one or more scan chains and with outputs coupled to one or more selected internal nodes of the circuit, wherein each of the one or more node-connecting devices is configured to receive an N-bit signal (N being 1, 2, or 3) directly or indirectly from N scan cells of the one or more scan chains and to at least cause, based on the N-bit signal, one of the one or more selected internal nodes to be either coupled to or decoupled from another node of the circuit. The each of the one or more node-connecting devices may comprise a switching device configured to couple or decouple the internal node to or from the one of two other nodes based on the N-bit signal. The switching device may be a transistor.

The one or more selected nodes may be selected based at least on user specification, circuit topology, simulation of the circuit and the circuit injected with defects, or any combination thereof.

N may be 1 or 2 and each of at least some of the one or more node-connecting devices is configured to cause, based on a 2-bit signal, a selected internal node to be coupled to either or neither of two other nodes of the circuit. The each of at least some of the one or more node-connecting devices may comprise circuitry configured to prevent the selected internal node from being connected to the two other nodes simultaneously.

Each of the one or more threshold-comparing sub-convertors may be an inverter formed by two transistors.

Each of the one or more threshold-comparing sub-convertors may be a multiplexer which a scan cell also uses to select either a parallel input or a serial input.

The test patterns may be generated based on random combinations of bit values or all combinations of bit values.

Each of the one or more threshold-comparing convertors may comprise at most four threshold-comparing sub-convertors.

The circuit may further comprise update register elements coupled to parallel outputs of the one or more scan chains.

The bit value of the test response may be treated as being indeterminate if the voltage value at the selected node is within a preset range centered at the one of the one or more preset thresholds. Alternatively or additionally, the bit value of the test response may be treated as being indeterminate if the bit value obtained by simulating the circuit for one combination of process parameter values is not the same as the bit value obtained by simulating the circuit for a different combination of process parameter values.

In another aspect, there are one or more non-transitory computer-readable media storing computer-executable instructions for causing one or more processors to perform a method, the method comprising: creating, in a circuit design being at least partially analog, a test circuit according to any of claims 1 to 14.

Certain inventive aspects are set out in the accompanying independent and dependent claims. Features from the dependent claims may be combined with features of the independent claims and with features of other dependent claims as appropriate and not merely as explicitly set out in the claims.

Certain objects and advantages of various inventive aspects have been described herein above. Of course, it is to be understood that not necessarily all such objects or advantages may be achieved in accordance with any particular embodiment of the disclosed techniques. Thus, for example, those skilled in the art will recognize that the disclosed techniques may be embodied or carried out in a manner that achieves or optimizes one advantage or group of advantages as taught herein without necessarily achieving other objects or advantages as may be taught or suggested herein.

### BRIEF DESCRIPTION OF THE DRAWINGS

FIG. 1A illustrates an example scan chain.

FIG. 1B illustrates an example scan chain along with update storage elements.

FIG. 2 illustrates an example of scan-based test circuitry for testing an analog/mixed-signal circuit according to various embodiments of the disclosed technology.

FIG. 3A illustrates an example CMOS inverter serving as a threshold-comparing sub-convertor with a high threshold and its transfer function curve.

FIG. 3B illustrates an example CMOS inverter serving as a threshold-comparing sub-convertor with a low threshold and its transfer function curve.

FIG. 3C illustrates an example bias voltage generator.

FIG. 3D illustrates an example threshold-comparing convertor comprising two threshold-comparing sub-convertors that have two different thresholds and its transfer function curve.

FIG. 4A illustrates an example of multiplexer-implemented threshold-comparing convertors according to various embodiments of the disclosed technology.

FIG. 4B illustrates an example threshold-comparing convertor that comprises two multiplexer-implemented threshold-comparing sub-convertors according to various embodiments of the disclosed technology.

FIG. 5 illustrates an example threshold-comparing convertor that comprises four threshold-comparing sub-convertors and an encoder according to various embodiments of the disclosed technology.

FIG. 6 illustrates an example of scan-based test circuitry for testing an analog/mixed-signal circuit, the scan-based test circuitry further comprising node-connecting devices configured to help apply test stimuli to the analog or mixed-signal circuit according to various embodiments of the disclosed technology.

FIG. 7A illustrates an example node-connecting device comprising a switching device implemented using a PMOS transistor.

FIG. 7B illustrates an example node-connecting device comprising a switching device implemented using an NMOS transistor.

FIG. 7C illustrates an example node-connecting device comprising two switching devices implemented using two transistors, respectively.

FIG. 8 illustrates two examples of circuitry configured to prevent a node-connecting device from coupling an internal node to two other nodes simultaneously according to various embodiments of the disclosed technology.

FIG. 9A illustrates an example circuit schematic diagram for an analog circuit.

FIG. 9B illustrates an example netlist for the analog circuit in FIG. 9A.

FIG. 9C illustrates example netlists for three node-connecting devices coupled to the three selected internal nodes for injecting test stimuli and an example netlist for a threshold-comparing convertor coupled to one of the three selected nodes for observing test responses.

FIG. 10 illustrates an example circuit schematic diagram for a circuit comprising both analog and digital circuitry.

FIG. 11 illustrates a flowchart showing a process of determining and removing testing circuitry not uniquely contributing to detecting defects that may be implemented according to various examples of the disclosed technology.

FIG. 12 illustrates an example of voltages applied to the analog inputs of the circuit in FIG. 9A, an example of nine sets of bit values applied as test stimuli to the circuit in FIG. 9A at nine consecutive time intervals, and an example of expected test response bit values captured during the nine consecutive time intervals.

FIG. 13 illustrates an example for determining indeterminate bits in the expected test response bit values for the circuit in FIG. 9A.

FIG. 14A illustrates an example of forming a reduced set of test patterns based on a defect detection matrix for nine defects of the circuit in FIG. 9A.

FIG. 14B illustrates an example of forming a reduced set of short sequences of test patterns for testing the circuit in FIG. 9A.

FIG. 15A illustrates a set of test patterns applied to the circuit in FIG. 9A during nine consecutive time intervals.

FIG. 15B illustrates a reduced set of test patterns for three time intervals and without rows for the NMOS transistor (dftn0) and the PMOS transistor (dftp5).

FIG. 15C illustrates how the reduced set of three test patterns might be shifted in a serial bit stream applied to a scan chain.

FIG. 16A illustrates an example defect detection matrix for the circuit in FIG. 9A in terms of both the reduced set of test pattern bit locations and test response bit locations.

FIG. 16B illustrates an example of expected test response bit values for each of the threshold-comparing sub-convertors for nine consecutive time intervals with the reduced set of test patterns outlined.

FIG. 16C illustrates expected test response bit values only for three time intervals associated with the reduced set of test patterns.

FIG. 16D illustrates a minimized set of expected test response bit values only for the threshold-comparing sub-convertors retained.

FIG. 16E illustrates how the minimized set of expected test response bit values might be shifted out along a scan chain.

FIG. 17 illustrates an example of test circuitry for the circuit in FIG. 9A.

FIG. 18 illustrates an example of a programmable computer system with which various embodiments of the disclosed technology may be employed.

### DETAILED DESCRIPTION OF THE DISCLOSED TECHNIQUES

Various aspects of the disclosed technology relate to scan-based test circuitry for structural testing of analog and mixed-signal circuits. In the following description, numerous details are set forth for the purpose of explanation. However, one of ordinary skill in the art will realize that the disclosed technology may be practiced without the use of these specific details. In other instances, well-known features have not been described in details to avoid obscuring the disclosed technology.

Some of the techniques described herein can be implemented in software instructions stored on a computer-readable medium, software instructions executed on a computer, or some combination of both. Some of the disclosed techniques, for example, can be implemented as part of an electronic design automation (EDA) tool. Such methods can be executed on a single computer or on networked computers.

Although the operations of the disclosed methods are described in a particular sequential order for convenient presentation, it should be understood that this manner of description encompasses rearrangements, unless a particular ordering is required by specific language set forth below. For example, operations described sequentially may in some cases be rearranged or performed concurrently. Moreover, for the sake of simplicity, the disclosed flow charts and block diagrams typically do not show the various ways in which particular methods can be used in conjunction with other methods.

The detailed description of a method or a device sometimes uses terms like “configure” and “output” to describe the disclosed method or the device function/structure. Such terms are high-level descriptions. The actual operations or functions/structures that correspond to these terms will vary depending on the particular implementation and are readily discernible by one of ordinary skill in the art.

As used in this disclosure, the singular forms “a,” “an,” and “the” include the plural forms unless the context clearly dictates otherwise. Additionally, the term “includes” means “comprises.” Moreover, unless the context dictates otherwise, the term “coupled” means electrically or electromagnetically connected or linked and includes both direct connections or direct links and indirect connections or indirect links through one or more intermediate elements not affecting the intended operation of the circuit.

Additionally, as used herein, the term “design” is intended to encompass data describing an entire integrated circuit device. This term also is intended to encompass a smaller group of data describing one or more components of an entire device such as a portion of an integrated circuit device nevertheless.

As noted previously, testing typically includes applying test patterns to a circuit-under-test and then capturing and analyzing responses generated by the circuit-under-test. To make it easier to develop and apply test patterns, certain testability features are added to circuit designs, which is referred to as design for test or design for testability (DFT). Scan testing is the most common DFT method. In a basic scan testing scheme, all or most of internal sequential state elements (latches, flip-flops, et al.) in a circuit design are made controllable and observable via a serial interface. These functional state elements are usually replaced with dual-purpose state elements called scan cells. Scan cells are connected together to form scan chains-serial shift registers for shifting in test patterns and for capturing and shifting out test responses. Being dual-purpose, a scan cell can operate as a state element originally intended for functional purposes in functional/mission mode and as a unit in a scan chain for scan testing in test mode.

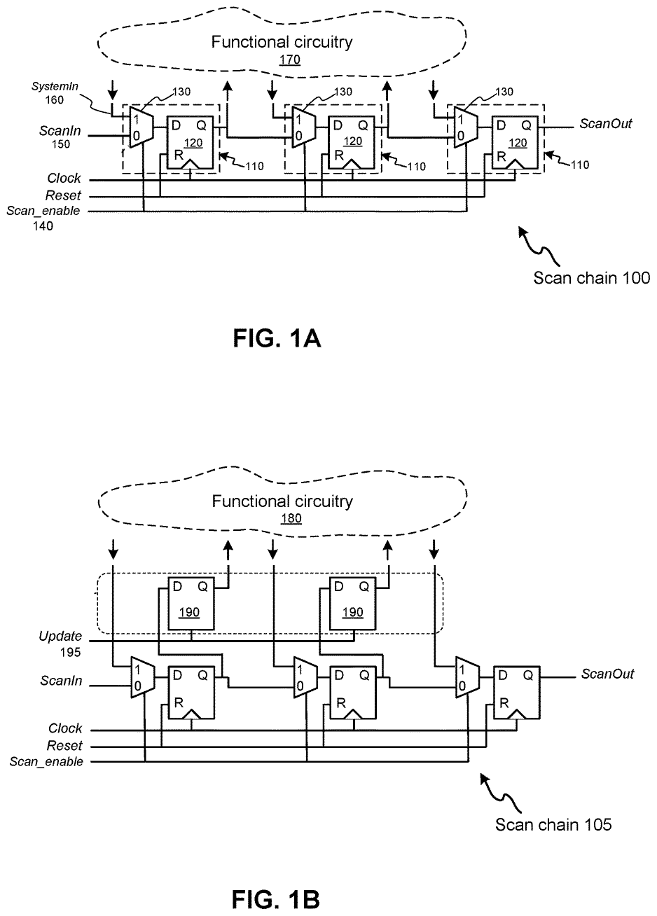

FIG. 1A illustrates an example of a scan chain 100. The scan chain 100 comprises a plurality of scan cells 110. Each of the scan cells 110 comprises an edge-trigged flip-flop 120 with a two-way multiplexer 130 for the data input. The two-way multiplexer 130 is typically controlled by a control signal 140 called scan_enable, which selects the input signal for the scan cell 110 from either a scan signal input port 150 or a system signal input port 160 (sometimes referred to as parallel input). The scan signal input port 150 is typically connected to an output of another scan cell in the scan chain 100 while the system signal input port 160 is connected to functional circuitry 170. Each of the scan cells 110 fans out into two outputs: a serial output coupled to the scan cell in the scan chain 100 and a parallel output coupled to functional circuitry 170.

In test mode, a scan cell like the scan cell 110 can serve as a control point that applies a test stimulus bit to the circuit-under-test, an observation point that captures a test response bit generated by the circuit-under-test, or both. Test mode typically includes two types of operations: shift operation (shift mode) and capture operation (capture mode). In the shift operation, a series of clock pulses, called “shift pulses” or “shift clock pulses,” are applied to the scan cells. Each shift clock pulse pushes a bit of a test pattern into a scan cell in each of the scan chains. This continues until all scan cells in the scan chains are filled with test pattern bits. In the capture operation, one or more clock pulses, called “capture pulses” or “capture clock pulses,” are applied to both the scan cells and the circuit-under-test as they would be in normal operation. After the test pattern bits stored in the scan cells are injected into the circuit-under-test, the results of the test (test responses) are “captured” and stored in the scan cells. The scan cells then return to the shift operation, and with each additional clock pulse, a bit of the test responses is pushed or shifted out along the scan chains as each bit of a new test pattern is pushed or shifted in. The shifted-out test responses are then compared with expected results to determine and locate any errors.

FIG. 1B illustrates another example of a scan chain 105. Unlike the scan chain 100 in FIG. 1A, parallel outputs of the scan chain 105 are coupled to functional circuitry 180 indirectly via update storage elements 190. The signals applied to the functional circuitry 180 can only change when an update clock signal 195 is toggled instead of whenever shifting occurs in the scan chain 105. This can prevent shifting from changing the state of the functional circuitry 180. Another benefit is the reduction of toggling activities in the shift operation which can significantly lower power consumptions and prevent the circuit from overheating. The update storage elements 190 can be implemented using latches or flip-flops.

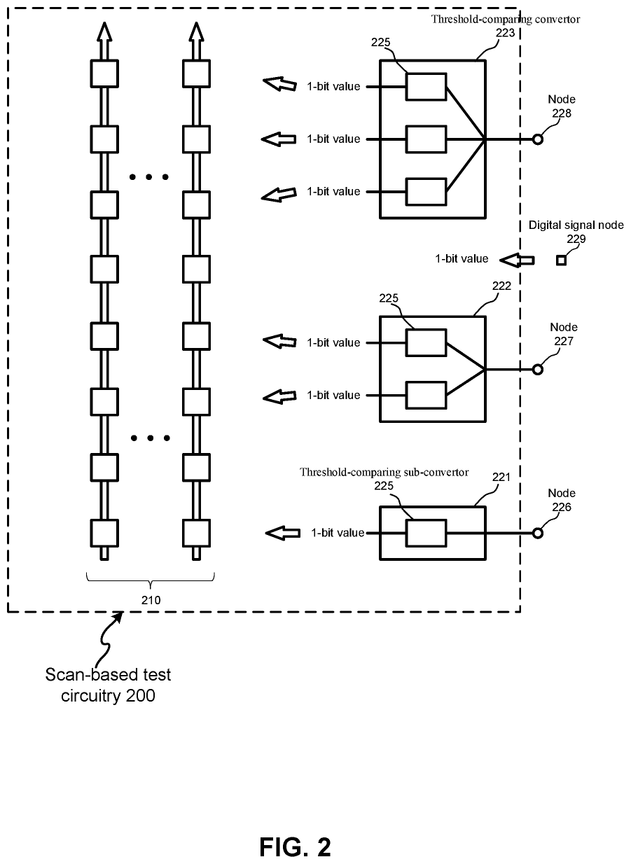

FIG. 2 illustrates an example of scan-based test circuitry 200 for testing an analog/mixed-signal circuit according to various embodiments of the disclosed technology. The scan-based test circuitry 200 comprises one or more scan chains 210 and threshold-comparing convertors 221, 222 and 223. The one or more scan chains 210 are configured to shift in and apply test patterns, and to capture and shift out test responses during a test. The threshold-comparing convertors 221, 222 and 223 have inputs coupled to selected nodes 226, 227 and 228 of the analog/mixed-signal circuit, respectively and outputs coupled to parallel inputs of the one or more scan chains 210. The threshold-comparing convertors 221, 222 and 223 can be configured to convert voltages at the selected nodes 226, 227 and 228 into test response bit values which can then be captured by the one or more scan chains 210 during a test.

As shown in FIG. 2, the threshold-comparing convertors 221, 222 and 223 comprise one, two and three threshold-comparing sub-convertors 225, respectively. Each threshold-comparing sub-convertor 225 is configured to output a bit value based on comparing a voltage value at the associated selected node with a preset threshold. Specifically, the threshold-comparing convertor 221 can use one threshold-comparing sub-convertor 225 to convert the voltage at the selected node 226 into a one-bit test response value; the threshold-comparing convertor 222 can use two threshold-comparing sub-convertors 225 to convert the voltage at the selected node 227 into two one-bit test response values; and the threshold-comparing convertor 223 can use three threshold-comparing sub-convertors 225 to convert the voltage at the selected node 228 into three one-bit test response values. These digitized test response values can then be captured by the one or more scan chains 210. Typically, thresholds used by threshold-comparing sub-convertors in the same threshold-comparing convertor are set to be different from each other while thresholds used by threshold-comparing sub-convertors in different threshold-comparing convertors can be set to be the same or different.

Some circuits may have one or more digital signal nodes selected for observing test responses like a node 229. The test response bits at these selected digital signal nodes can be captured by the one or more scan chains 210 directly without using threshold-comparing convertors.

It should be noted that while the threshold-comparing convertors 221, 222 and 223 are shown to have at most three threshold-comparing sub-convertors, threshold-comparing convertors may comprise more than three threshold-comparing sub-convertors in some embodiments of the disclosed technology. In some other embodiments of the disclosed technology, each threshold-comparing convertor may comprise just one threshold-comparing sub-convertor. In still some other embodiments of the disclosed technology, each threshold-comparing convertor may comprise two threshold-comparing sub-convertors. It should also be noted that a scan chain can be coupled to outputs of a threshold-comparing convertor directly or indirectly. For example, a threshold-comparing convertor having four threshold-comparing sub-convertors can have outputs connected to an encoding device which is configured to convert a five possible output combination into a three-bit value. The outputs of the encoding device are connected to three scan cells of the scan chain.

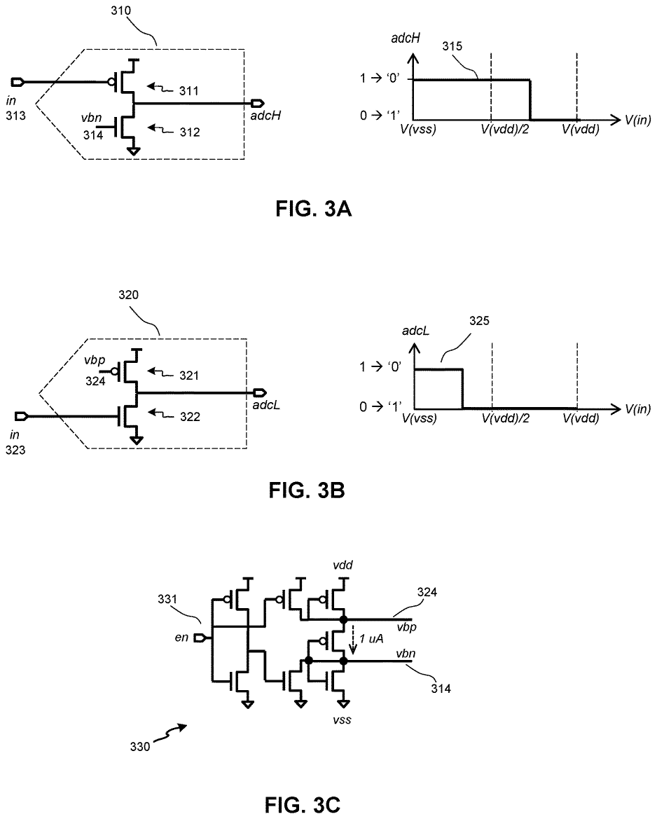

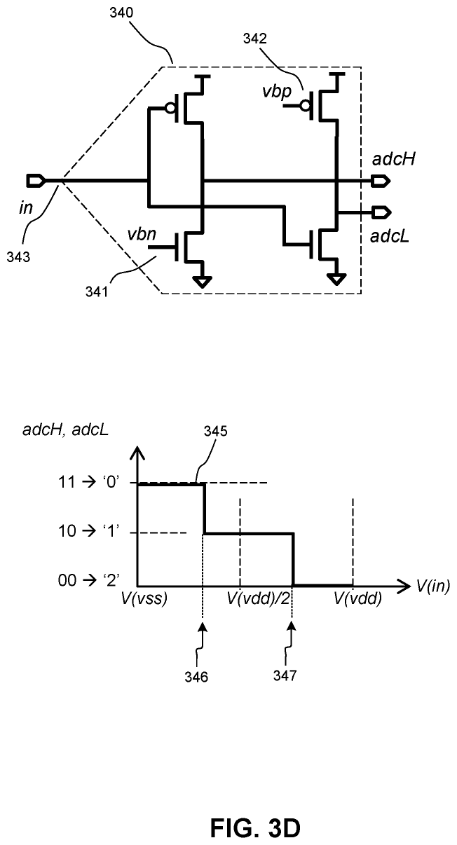

Threshold-comparing sub-convertors can be implemented using complementary metal-oxide semiconductor (CMOS) inverters. Each CMOS inverter can be constructed using a pair of p-type and n-type transistors. FIGS. 3A and 3B illustrate two examples of CMOS inverters 310 and 320 serving as threshold-comparing sub-convertors and corresponding transfer function curves 315 and 325. In FIG. 3A, the CMOS inverter 310 comprises a p-type transistor 311 and an n-type transistor 312. The gate of the p-type transistor 311 is coupled to an input voltage signal 313 and the gate of the n-type transistor 312 is coupled to a bias voltage 314. The transfer function curve 315 shows that the voltage threshold is higher than mid-way between the power supply voltage and ground. Based on whether the value of the input voltage signal 313 is greater than the voltage threshold or not, the CMOS inverter 310 can output a logic “1” or “0”. In FIG. 3B, the CMOS inverter 320 comprises a p-type transistor 321 and an n-type transistor 322. The gate of the p-type transistor 321 is coupled to a bias voltage 324 and the gate of the n-type transistor 322 is coupled to the input voltage signal 323. The transfer function curve 325 shows that the voltage threshold is lower than mid-way between the power supply voltage and ground. Based on whether the value of the input voltage signal 323 is greater than the voltage threshold or not, the CMOS inverter 320 can output a logic “0” or “1”. FIG. 3C illustrates an example bias voltage generator 330. When an enable signal 331 is “1”, the bias voltage generator 330 can generate the bias voltages 314 and 324.

FIG. 3D illustrates an example threshold-comparing convertor 340 comprising two threshold-comparing sub-convertors 341 and 342 that have two different thresholds and a corresponding transfer function curve 345. The two threshold-comparing sub-convertors 341 and 342 can be implemented using the CMOS inverters 310 and 320, respectively. As the corresponding transfer function curve 345 shows, the threshold-comparing convertor 340 is equivalent to a 1.5-bit analog-to-digital convertor: outputting one 2-bit code when an input voltage 343 is below a first threshold 346, a second 2-bit code when the input voltage 343 is above the first threshold 346 but less than a second threshold 347, and a third 2-bit code when the input voltage 343 is above the second threshold 347. The first threshold 346 is approximately an NMOS transistor's threshold voltage higher than the reference ground voltage, and the second threshold 347 is approximately a PMOS transistor's threshold voltage lower than the reference power supply voltage.

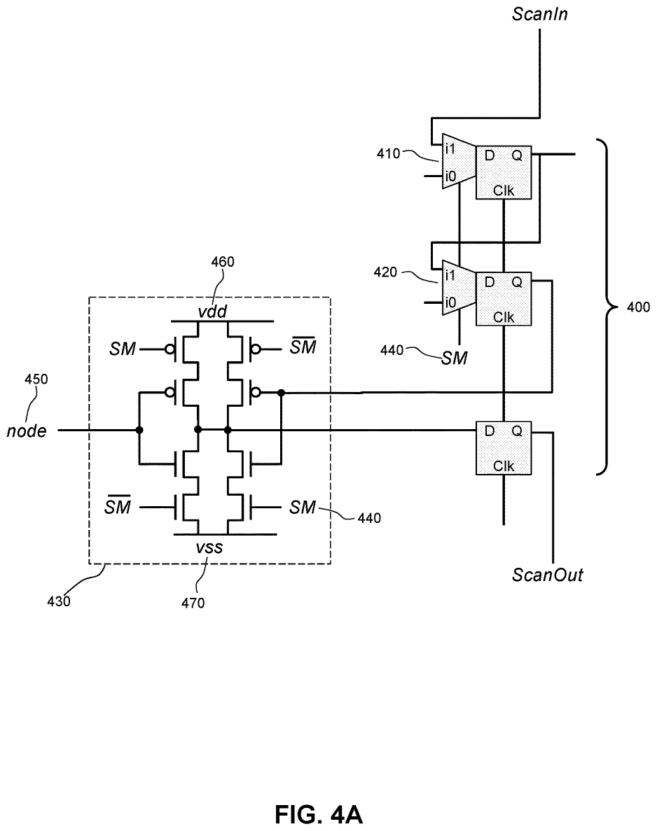

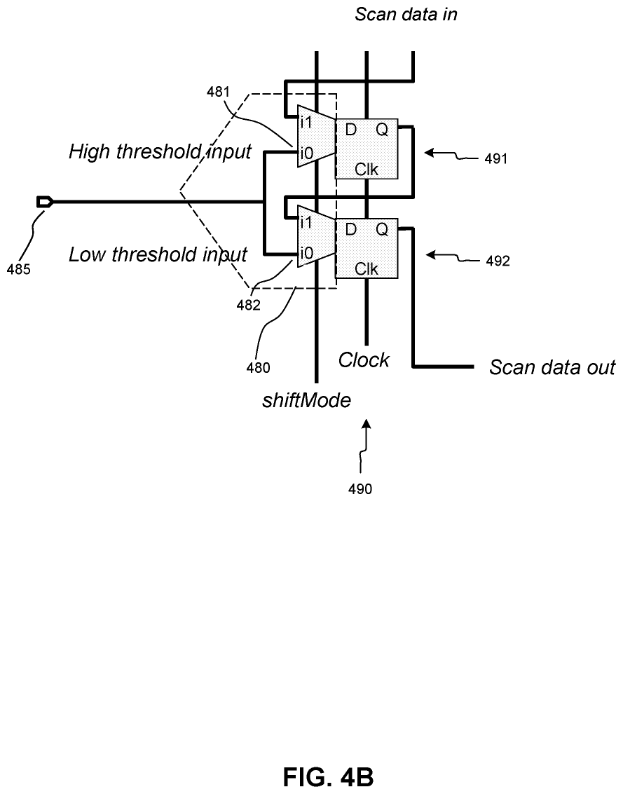

Threshold-comparing sub-convertors can also be implemented using a logic gate with a voltage threshold that is designed to be at or offset from midrange between the power supply and the ground. FIG. 4A illustrates an example of multiplexer-implemented threshold-comparing convertors 410-430 according to various embodiments of the disclosed technology. Each of the multiplexer-implemented threshold-comparing convertors 410-430 is essentially a multiplexer. These multiplexers serve not only as threshold-comparing sub-convertors to convert test response voltage values into one-bit digital values but also as input multiplexers for corresponding scan cells in a scan chain 400 to select between parallel inputs and serial inputs. The latter role is just like how the two-way multiplexers 130 operate for the scan chain 100 in FIG. 1A.

FIG. 4A also illustrates an example schematic diagram of the multiplexer 430. When a selection signal 440 (SM) is “0”, the multiplexer 430 processes a voltage value at a node 450 and outputs the result to the corresponding scan cell. If the voltage value at the node 450 is higher than midrange between a power supply node 460 (vdd) and a ground node 470 (vss), the multiplexer 430 will output a bit of “0”; and if the voltage value at the node 450 is lower than the midrange, the multiplexer 430 will output a bit of “1”. The multiplexer 430 thus operates like a CMOS invertor with a midrange threshold in capture operation (SM=0) of the scan chain 400. The multiplexers 410 and 420 can use the same circuitry as the multiplexer 430. The circuit architecture that uses input multiplexers of scan cells to serve as a threshold-comparing convertors simultaneously can reduce silicon area cost of the test circuitry.

FIG. 4B illustrates an example threshold-comparing convertor 480 that comprises two multiplexer-implemented threshold-comparing sub-convertors 481 and 482 according to various embodiments of the disclosed technology. Like the multiplexers 410-430 in FIG. 4A, the multiplexers 481 and 482 serve as both threshold-comparing sub-convertors and input multiplexers for the scan cells 491 and 492 in a scan chain 490, respectively. However, the multiplexers 481 and 482 have two different voltage thresholds rather than the midrange voltage threshold used by the multiplexer 430 since they are configured to convert voltage values at an input 485 into digital values. Specifically, the multiplexer 481 is configured to convert the voltage value at the input 485 of the threshold-comparing convertor 480 to a first digit value based on a preset threshold higher than midrange between the power rails; and the multiplexer 482 is configured to convert the same voltage value to a second digit value based on a preset threshold lower than the midrange. The first and second digit values of the converted test response voltage at the node 450 can be captured by the scan cells 491 and 492, respectively. The multiplexers 481 and 482 can be implemented by modifying the circuitry of the multiplexer 430 in FIG. 4A. To construct the multiplexer 481, an N-type transistor gated by a reference voltage may be inserted to raise the threshold above the midrange. To construct the multiplexer 482, a p-type transistor gated by another reference voltage may be inserted to lower the threshold below the midrange. These reference voltages may be generated by the circuit 330 in FIG. 3C.

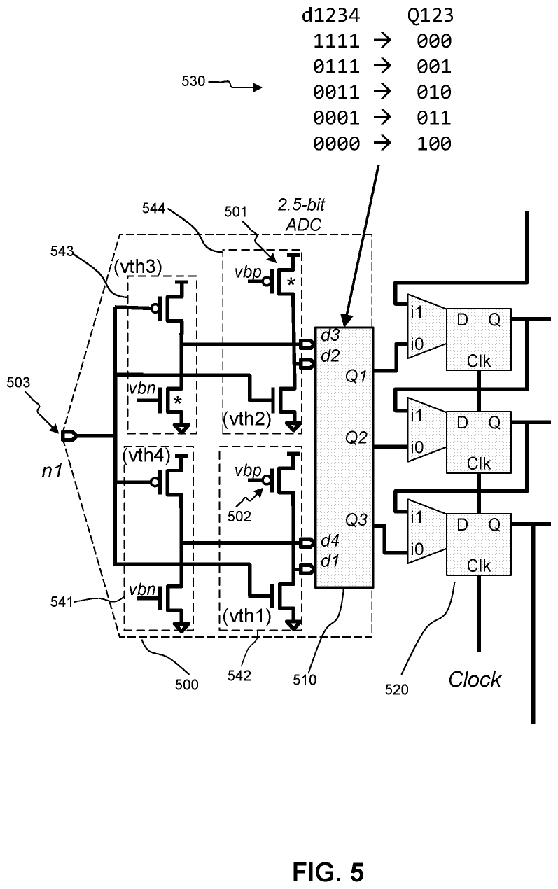

FIG. 5 illustrates an example threshold-comparing convertor 500 that comprises four threshold-comparing sub-convertors 541-544 and an encoder 510 according to various embodiments of the disclosed technology. The threshold-comparing convertor 500 is configured to digitize a test response voltage at a node 503, and result can be captured by a scan chain 520. To achieve it, each of the four threshold-comparing sub-convertors 541-544 has a unique voltage threshold. Inputs of the threshold-comparing sub-convertors 541 and 543 are coupled to gates of p-type transistors and thus their voltage thresholds are higher than midrange between the power rails; and inputs of the threshold-comparing sub-convertors 542 and 544 are coupled to gates of n-type transistors and thus their voltage thresholds are lower than the midrange. For two threshold-comparing sub-convertors that use gates of the same type of transistors as inputs, unique voltage thresholds can be obtained if the same type of transistors have different parameters. For example, transistors 501 and 502 have different parameters even though they are both p-type transistors and use the same bias voltage source vbp. The different parameters cause the two threshold-comparing sub-convertors 542 and 544 to have different voltage thresholds.

The four voltage thresholds used by the threshold-comparing sub-convertors 541-544 divide the range between the power supply and the ground into five regions. Accordingly, the voltage at input 503 of the threshold-comparing convertor 500 can be converted by the four threshold-comparing sub-convertors into one of five four-bit values. Four scan cells in a scan chain 520 can be employed to capture these four-bit values directly. FIG. 5, however, illustrates a different approach. The encoder 510 is configured to convert the five four-bit values into five three-bit values as shown by an example conversion table 530. This reduces the number of scan cells needed for capture operation from four to three. In effect, the threshold-comparing convertor 500 functions like a 2.5 bit analog-to-digital convertor.

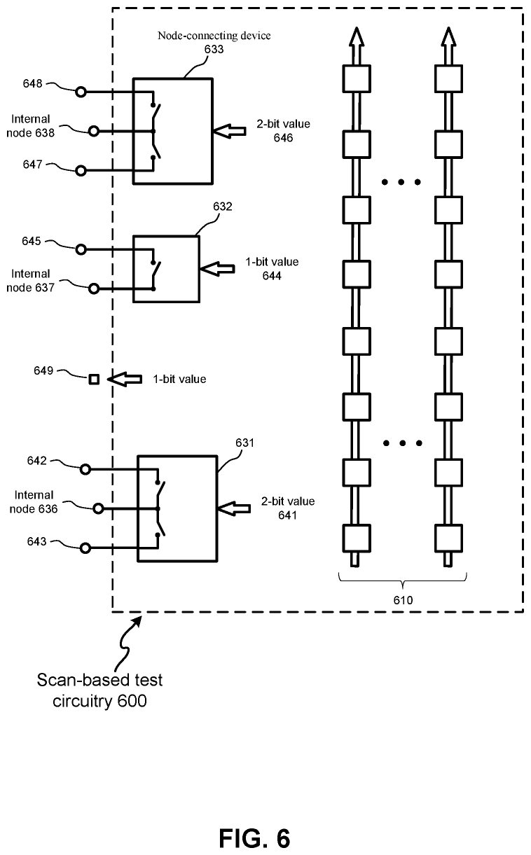

In addition to threshold-comparing convertors and one or more scan chains as illustrated in FIG. 2, the test circuitry for testing an analog or mixed-signal circuit may further comprise, according to various embodiments of the disclosed technology, one or more node-connecting devices with inputs coupled to the one or more scan chains and with outputs coupled to one or more selected internal nodes of the analog or mixed-signal circuit. These node-connecting devices are configured to help apply test stimuli to the analog or mixed-signal circuit. FIG. 6 illustrates such an example of scan-based test circuitry 600 for testing an analog/mixed-signal circuit. The scan-based test circuitry 600 is shown to comprise one or more scan chains 610 and node-connecting devices 631, 632 and 633. Threshold-comparing convertors in the scan-based test circuitry 600 are not shown in the figure. The node-connecting devices 631, 632 and 633 have inputs coupled to parallel outputs of the one or more scan chains 610 and outputs coupled to selected internal nodes 636, 637 and 638 and their associated nodes of the analog/mixed-signal circuit, respectively. The node-connecting devices 631, 632 and 633 can be configured to apply test stimuli to the analog/mixed-signal circuit via the selected internal nodes 636, 637 and 638 and their associated nodes during a test based on test pattern bit values loaded in the one or more scan chains 610.

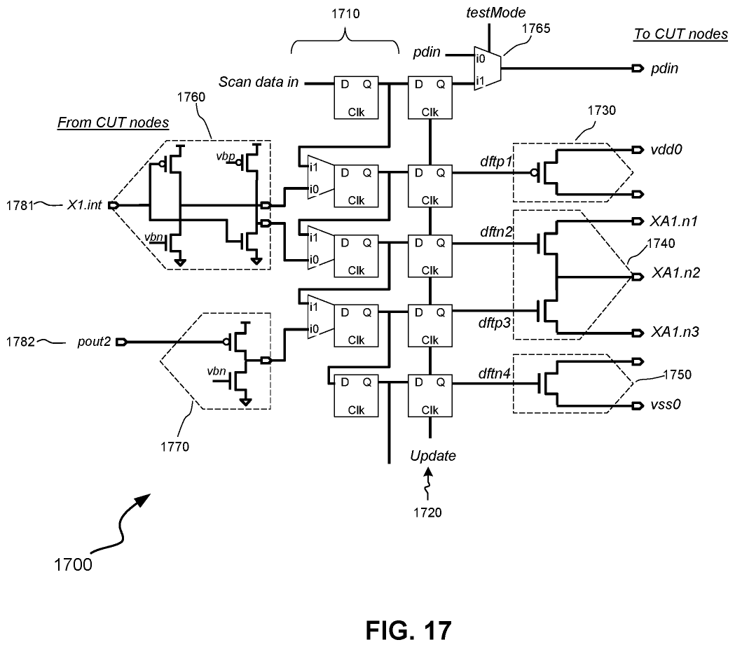

As shown in FIG. 6, the node-connecting devices 631, 632 and 633 comprise two, one and two switching devices, respectively. These switching devices can cause the selected internal nodes 636, 637 and 638 to be either coupled to or decoupled from their associated nodes based on bit values outputted by the one or more scan chains 610. Specifically, a two-bit value 641 enables the selected internal node 636 to be coupled to either a node 642, or a node 643, or none of them; a one-bit value 644 enables the selected internal node 637 to be either coupled to or decoupled from a node 645; and a two-bit value 646 enables the selected internal node 638 to be coupled to either a node 647, or a node 648, or none of them. In addition to selected internal nodes, some circuits may have one or more digital signal nodes like a node 649 selected for applying test pattern bits. Some other circuits may have only digital signal nodes selected for applying test pattern bits. In either of these two cases, test pattern bits stored in the scan chains can be applied to these selected digital signal nodes via digital multiplexers (see an example multiplexer 1765 in FIG. 17) without using node-connecting devices.

It should be noted that while the node-connecting devices 631, 632 and 633 are shown to have at most two switching devices, node-connecting devices may comprise more than two switching devices in some embodiments of the disclosed technology. In some other embodiments of the disclosed technology, each node-connecting device may comprise two switching devices. It should also be noted that the inputs of the node-connecting devices 631, 632 and 633 may be coupled directly or indirectly to parallel outputs of the one or more scan chains 610. In the indirect coupling, update storage elements like the update storage elements 190 in FIG. 1B can be inserted between inputs of the node-connecting devices 631, 632 and 633 and parallel outputs of the one or more scan chains 610.

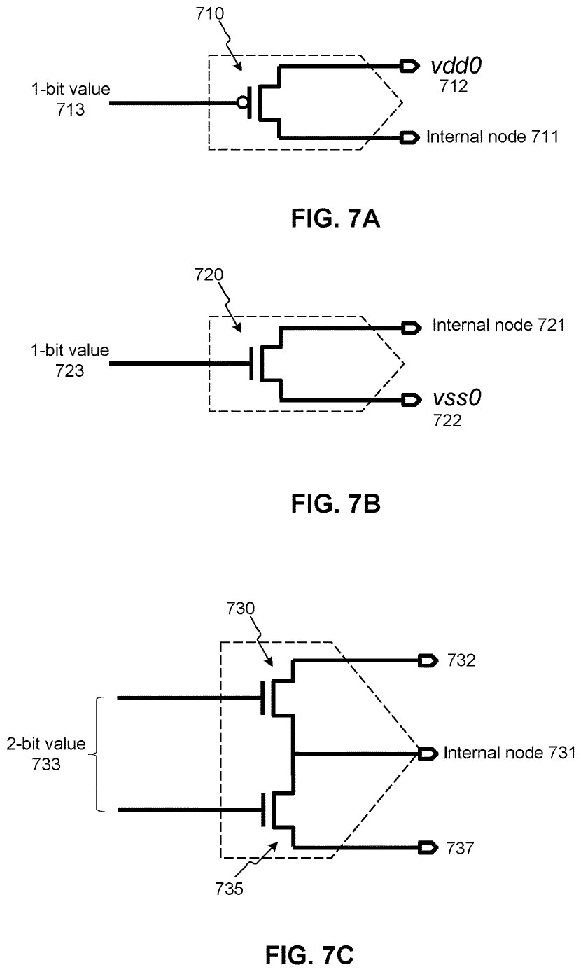

Switching devices in a node-connecting device can be implemented using transistors such as metal oxide semiconductor field-effect transistors (MOS FETs) according to various embodiments of the disclosed technology. FIGS. 7A, 7B and 7C illustrates three such examples. In FIG. 7A, a transistor 710 can connect an internal node 711 to a power supply node (vdd0) 712 when a 1-bit value 713 at its gate is “0” and disconnect the internal node 711 from the power supply node (vdd0) 712 when the 1-bit value 713 at its gate is “1”. In FIG. 7B, a transistor 720 can connect an internal node 721 to a ground node (vss0) 722 when a 1-bit value 723 at its gate is “1” and disconnect the internal node 721 from the power ground node (vss0) 722 when the 1-bit value 723 at its gate is “0”. While the node 712 is shown to be a power supply node and the node 722 is shown to be a ground node, they can also be any other nodes such as internal nodes.

In FIG. 7C, two transistors 730 and 735 can connect an internal node 731 to either a node 732, or a node 737, or none of them, based on a 2-bit code 733. Each of the nodes 732 and 737 can be a power supply node, a ground node, or another internal node. It should be noted that the two transistors 730 and 735 are typically of the same type, either NMOS or PMOS depending on the circuit, when the nodes 732 and 737 are of the same type, like the drains (or sources) of two transistors in a differential pair, whereas the two transistors 730 and 735 are typically of different types when one of the nodes 732 and 737 is a power supply node and the other is a ground node.

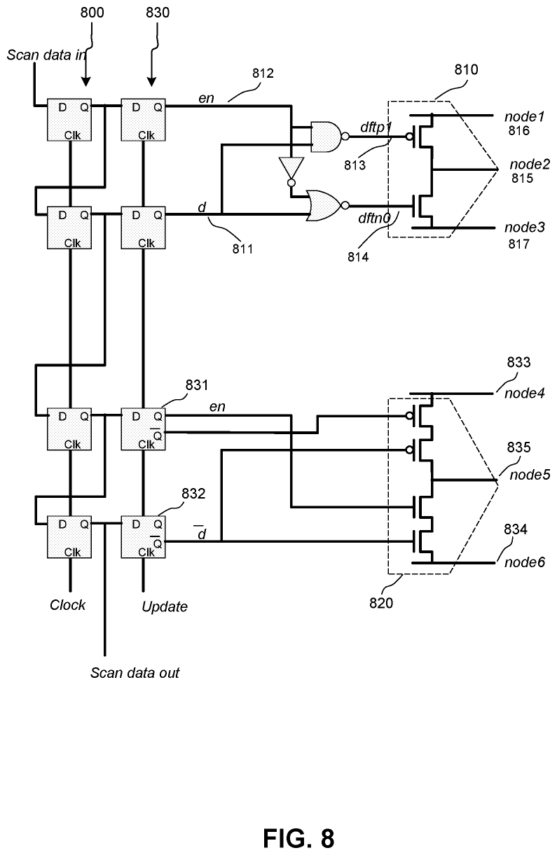

It is usually undesirable to simultaneously connect the three nodes 731, 732 and 737 together especially when one of the nodes 732 and 737 is a power supply node and the other is a ground node. Thus the particular value of the 2-bit code 733 enabling it should be avoided. This can be accomplished by adding some circuitry between scan cells and the gates of the switching devices 730 and 735 or into the node-connecting device itself. FIG. 8 illustrates example circuitry for these two approaches according to various embodiments of the disclosed technology. In the figure, a scan chain 800 is coupled to two node-connecting devices 810 and 820 via update storage elements 830. The node-connecting device 810 comprises two switching devices 813 and 814 and can couple an internal node 815 to either a node 816 or a node 817, or to decouple it from the two nodes 816 and 817 based on two bits 811 and 812. When the bit 812 is “0”, neither of the switching devices 813 and 814 is enabled. When the bit 812 is “1”, either the switching device 813 or the switching device 814 is enabled based on the bit 811. Random test pattern bits scanned into the scan chain 800 can lead to a 25% likelihood of the switching device 813 being enabled, a 25% likelihood of the switching device 814 being enabled, and a 50% likelihood of neither of the switching devices 813 and 814 being enabled.

While the node-connecting device 820 has a circuit topology different from the node-connecting devices 810, they function in a similar way. When a bit stored in an update storage element 831 is “1”, an internal node 835 is coupled to either a node 833 or a node 834 based on a bit stored in an update storage element 832. When the bit stored in the update storage elements 831 is “0”, the internal node 835 is decoupled from both the nodes 833 and 834 regardless of the bit stored in the update storage element 832.

In this disclosure, a node is any region of a circuit between two or more circuit elements. In circuit diagrams, connections are ideal wires with zero resistance, so a node is the entire section of wire between elements, not just a single point. An internal node of a circuit is a node connected to none of circuit inputs including power supply and ground and circuit outputs. A digital signal node is a node connected to at least an output or input of a digital circuit element like a logic gate.

The nodes for observing test responses can be selected based on user specification, circuit topology, or both. A node can be a good candidate for observing test responses if it has impedance low enough that connecting an input of threshold-comparing convertor to it would not affect the circuit's performance. Some examples of such low impedance nodes include outputs of functions and outputs of amplifiers. The IEEE P1687.2 Draft Standard for Test Access and Control provides an Instrument Connectivity Language (ICL) that specifies how to list properties of a circuit's test-related ports. These properties could be used to automatically identify suitable output ports of the circuit.

Similarly, the internal nodes for applying test stimuli can be selected based on user specification, circuit topology, or both. The number of circuit elements connected to a node, for example, may be used as a criterion for the selection. The more circuit elements that are connected to a node, the more potential defects the node-connecting device could activate. Additionally or alternatively, parameters of a circuit element may serve as criteria. According to various embodiments of the disclosed technology, a transistor's channel width may be considered as well. As an example of user specification, the source or drain of a transistor for which a user wants to add one or more switching devices for enhanced production burn-in testing can be selected as an internal node for applying test stimuli. Amplifiers are common analog devices and often include differential pairs. The common drain or source of a differential pair can be a good candidate as an internal node for applying test stimuli.

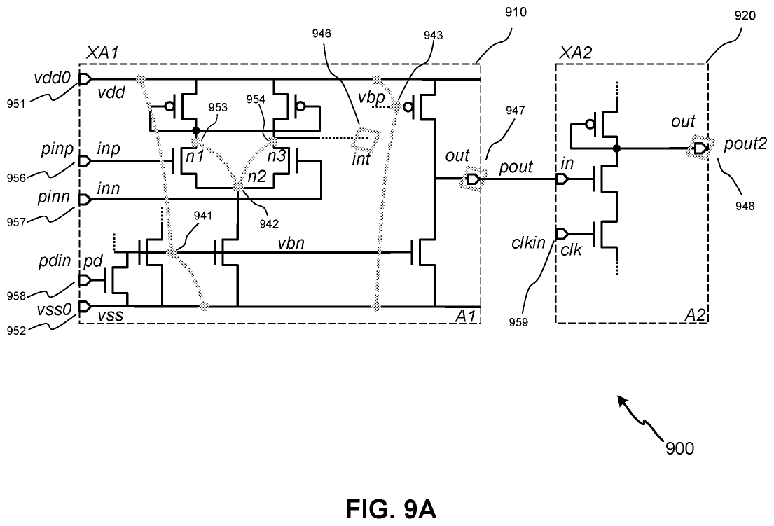

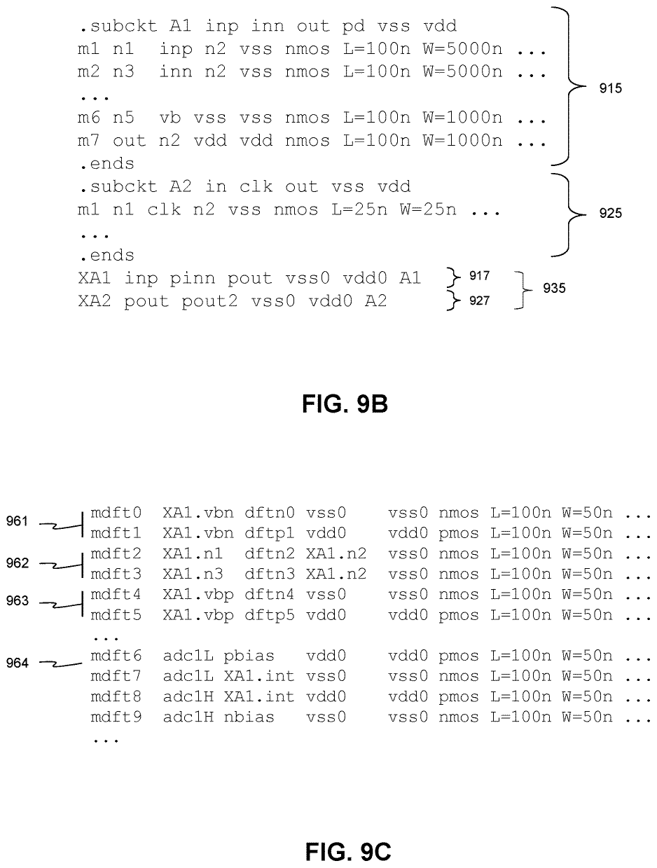

FIG. 9A illustrates an example circuit schematic diagram for a circuit 900 showing some circuit elements, internal circuit nodes selected for applying test stimuli, and circuit nodes selected for test response observation according to various embodiments of the disclosed technology. FIG. 9B illustrates an example netlist for the circuit 900. The circuit 900 includes two subcircuits 910 and 920. The netlist 915 represents the subcircuit 910, the netlist 925 represents the subcircuit 920, and the netlist 935 is a top-level netlist that includes instances 917 and 927 of the two subcircuits 910 and 920. The circuit 900 has function inputs 956 and 957, a power supply input 951, a ground input 952, a power-down input 958, and a clock input 959. The subcircuit 910 has an output 947; and the subcircuit 920 has an output 948.

In the circuit 900, internal nodes 941, 942 and 943 are selected for applying test stimuli; and a node 946 and the outputs 947 and 948 are selected for observing test responses. A node-connecting device comprising two switching devices can be inserted to control connections of the internal node 941 with the power supply node (vdd0) 951 and the ground node (vss0) 952. Similarly, another node-connecting device comprising two switching devices can be inserted to control connections of the internal node 943 with the power supply node (vdd0) 951 and the ground node (vss0) 952. Digitally enabling the connections during testing can increase the voltage swing on more nodes of the circuit 900 than signals applied to the analog inputs such as the inputs 956 and 957 would. This can cause minor flaws in transistor gate oxides to become latent defects that can be more easily detected by subsequent testing.

A third node-connecting device comprising two switching devices can be inserted to control connections of the internal node 942 with an internal node 953 and another internal node 954. Through the internal node 942 and the two associated internal nodes 953 and 954, the equivalent of a small offset voltage can be digitally injected, as a test stimulus, in a differential pair of transistors at the front-end of an operational amplifier. Such amplifiers can have very high gain, so a very small stimulus amplitude is needed to test that the gain is, in fact, high for each manufactured implementation of the circuit. The voltage at the node 947 can be used to check the gain. A threshold-comparing convertor comprising two threshold-comparing sub-convertors like the threshold-comparing convertor 340 shown in FIG. 3D may be employed for the purpose. Similarly, threshold-comparing convertors can be used to convert voltages at the nodes associated with the outputs 947 and 948 to digital test response bits for capturing. The node-connecting devices for injecting test pattern bits at the nodes 941 and 943 may be implemented using the node-connecting device shown in FIG. 7C in which the transistors 730 and 735 are of different types; and the node-connecting device for injecting test pattern bits at the node 942 may be implemented using the node-connecting device shown in FIG. 7C in which the transistors 730 and 735 are both NMOS. FIG. 9C illustrates example netlists 961, 962 and 963 for the three node-connecting devices and an example netlist 964 for the threshold-comparing convertor coupled to the node 947. The netlists 961, 962, 963 and 964 along with netlists for the threshold-comparing convertors coupled to the nodes 947 and 948 would be added to the top-level netlist.

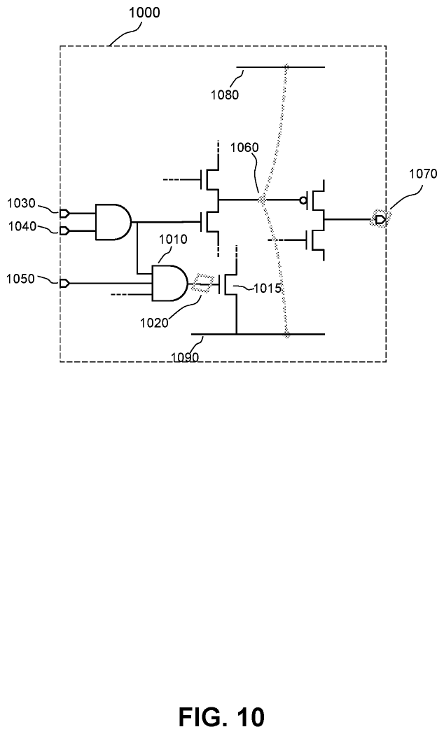

FIG. 10 illustrates an example circuit schematic diagram for a circuit 1000 comprising both analog and digital circuitry. The digital circuitry includes logic gates such as an AND gate 1010. An output 1020 of the AND gate 1010 directly drives an analog transistor 1015. Such an output node 1020 has low impedance and thus can be selected for observing test responses. A threshold-comparing convertor with a midrange threshold can be employed for the purpose. Some or all of digital signal inputs 1030, 1040 and 1050 (digital signal nodes) can be selected for injecting test pattern bits in test mode via digital multiplexers. No node-connecting device is needed. An internal node 1060 can also be selected for injecting test pattern bits. A node-connecting device can be inserted to connect the internal node 1060 to either a power supply node 1080 or a ground node 1090, and to disconnect the internal node 1060 from both the supply node 1080 and the ground node 1090. An output node 1070 can be selected for observing test responses as well. A threshold-comparing convertor can be employed for the purpose.

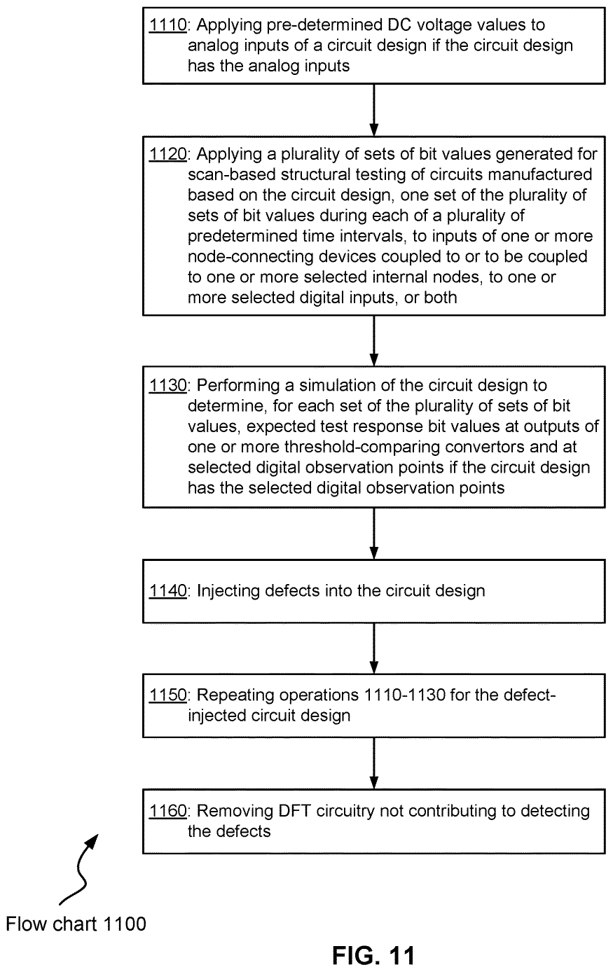

Testing circuitry not uniquely contributing to detecting defects can be identified and removed by simulating both defect-free and defect-injected circuit designs. FIG. 11 illustrates a flowchart 1100 showing a process of determining and removing testing circuitry not uniquely contributing to detecting defects that may be implemented according to various examples of the disclosed technology. For ease of understanding, methods for determining testing circuitry not uniquely contributing to detecting defects that may be employed according to various embodiments of the disclosed technology will be described with reference to the circuit 900 shown in FIG. 9A and the flow chart 1100 illustrated in FIG. 11. It should be appreciated, however, that the methods for determining testing circuitry not uniquely contributing to detecting defects illustrated by the flow chart 1100 can be applied to an analog/mixed-signal circuit design different from the circuit 900 in FIG. 9A according to various embodiments of the disclosed technology. Likewise, the circuit 900 may be simulated using other methods for determining testing circuitry not uniquely contributing to detecting defects according to various embodiments of the disclosed technology.

In operation 1110, pre-determined DC voltage values are applied to analog inputs of a circuit design if the circuit design has the analog inputs. The circuit design may be a whole circuit design or a portion of a circuit design such as a core or a circuit block in a circuit design. The circuit design is at least partially analog. Analog circuitry works with analog signals. An analog signal is a continuously variable signal as opposed to a digital signal made up of binary ups and downs (or pulses). With various implementations of the disclosed technology, the pre-determined DC voltage values may be set to be in the midrange of voltage values that would be applied to the analog inputs during the circuit's normal operation.

The circuit 900 has two analog function inputs 956 and 957. The range of voltage values that would be applied to them during the circuit's normal operation is between 0 and 3.0 volts. Accordingly, the pre-determined DC voltage values for the two analog function inputs 956 and 957 can be set to be 1.5 volts. The circuit 900 also has a clock input 959. A periodic clock signal at the nominal frequency of the clock input 959 can be applied to it. In addition to the clock input, some digital inputs such as reset signals may need to be treated specially. In the circuit 900, for example, a power-down signal for the power-down input 958 can be in its power-up mode for most test patterns and in power-down mode for at least some test patterns.

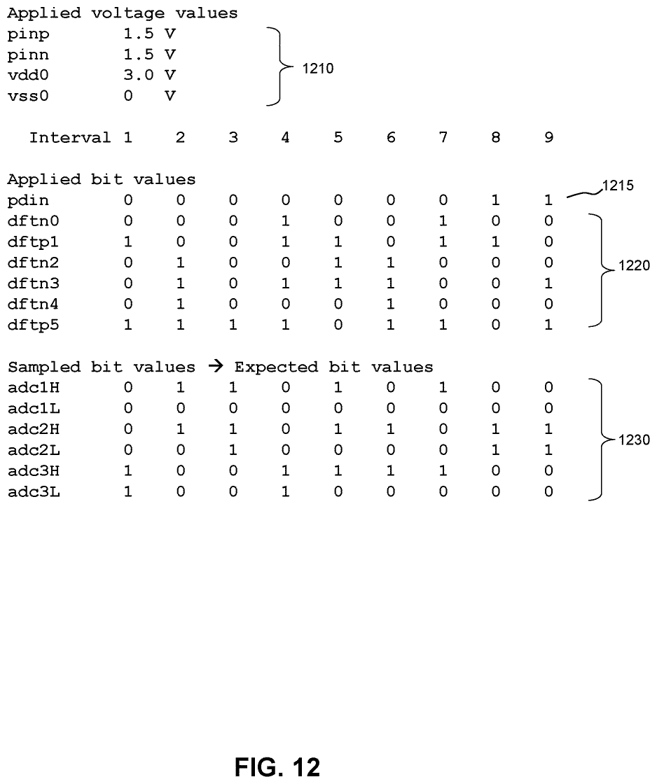

FIG. 12 illustrates an example of voltages applied to the analog inputs of the circuit 900. A block 1210 titled “Applied voltage values” shows that the voltages at the analog function inputs 956 and 957, the power supply input 951, and the ground input 952 are 1.5, 1.5, 3.0 and 0 volts, respectively. A row 1215 titled “pdin” shows the bit value at the power-down input 958, a specially-treated digital signal input. The bit value is “0” and the circuit 900 is in the power-up mode during the first seven time intervals; and the bit value is “1” and the circuit 900 is in the power-down mode during the last two time intervals.

Referring back to FIG. 11, in operation 1120, a plurality of sets of bit values are applied, one set of the plurality of sets of bit values during each of a plurality of consecutive time intervals, to inputs of one or more node-connecting devices coupled to or to be coupled to one or more selected internal nodes, to one or more selected digital inputs, or both. The one or more selected internal nodes and the one or more selected digital inputs can be selected based on user specification, circuit topology, or both. The number of circuit elements connected to an internal node, for example, may be used as a criterion for the selection of internal nodes. Additionally or alternatively, parameters of a circuit element may serve as criteria. According to various embodiments of the disclosed technology, a transistor's width may be considered as well.

Each of the one or more node-connecting devices is configured to at least cause one of the one or more selected internal nodes to be either coupled to or decoupled from another node of the circuit (a node associated with the one of the one or more selected internal nodes) based on bit values at inputs of the each of the one or more input node-connecting devices. To perform the function, each of the one or more node-connecting devices can comprise one or more switching devices like the node-connecting devices 631, 632 and 633 in FIG. 6. The switching devices can be implemented using transistors such as metal-oxide semiconductor field-effect transistors like the transistors 710, 720, 730 and 735 shown in FIGS. 7A-C. The circuit 900 can use two node-connecting devices to control the connections of the internal node 941 and the internal node 943 with the power supply node (vdd0) 951 and the ground node (vss0) 952, and a third node-connecting device to control the connection of the internal node 942 with the two associated internal nodes 953 and 954.

The plurality of sets of bit values applied as test stimuli are generated for scan-based structural testing of circuits manufactured based on the circuit design. The plurality of sets of bit values may be generated based on random combinations of bit values or all combinations of bit values for the inputs of the one or more node-connecting devices if the circuit design has the one or more selected internal nodes and for the one or more selected digital inputs if the circuit design has the one or more selected digital inputs. A pseudo-random pattern generator, such as a linear feedback shift register (LFSR) circuit or a software routine, may be employed for the random generation approach. According to various embodiments of the disclosed technology, the first set of bit values applied may be set to be the one that does not cause the one or more selected internal nodes to be coupled to their associated nodes. The defects that could be detected by this set of bit values can be considered as the ones detectable without adding any node-connecting devices. This can serve as a good reference because it is the circuit starting in a normal functional condition.

Each of the plurality of consecutive time intervals is equal to one or more clock cycles of a scan clock signal for the scan-based structural testing of circuits manufactured based on the circuit design. If the circuit design has a circuit's clock signal, each of the plurality of consecutive time intervals is also equal to one or more cycles of the circuit's clock signal. The time interval can begin when the circuit's clock signal rises, or when it falls — the choice of edge can be based on when the input signals to the circuit design are sampled by the circuit's clock signal, and when the outputs of the circuit design change. For example, if circuit nodes are initialized when the circuit's clock signal is logic 0, and output signals change shortly after the circuit's clock signal rises to logic 1, then each of the plurality of sets of bit values can be applied when the circuit's clock signal falls to logic 0. The time interval can be set to be large enough that all signals in the circuit design have settled to a constant value in the time interval so that the resulting circuit design output values will be more independent of the sequence of the plurality of sets of bit values, as is done typically for digital automatic test pattern generation (ATPG). This can allow plurality of sets of bit values to be reduced more which will be discussed later.

FIG. 12 also illustrates an example of nine sets of bit values 1220 applied as test stimuli to the circuit 900 at nine consecutive time intervals. The first two rows “dftn0” and “dftp1” in the nine sets of bit values 1220 represent bit values at the inputs of the NMOS and PMOS transistors coupled to the internal node 941; the next two rows “dftn2” and “dftn3” represent bit values at the inputs of the two NMOS transistors coupled to the internal node 942; and the last two rows “dftn4” and “dftp5” represent bit values at the inputs of the NMOS and PMOS transistors coupled to the internal node 943. The nine sets of bit values 1220 are randomly generated except the bit values for the first time interval. During the first time interval, the bit values are logic ‘0’ for each NMOS transistor gate and logic ‘1’ for each PMOS transistor gate. These bit values would not enable the transistors to convey current and thus decouple the internal nodes 941, 942 and 943 from their associated nodes. As such, the circuit 900 operates in a normal functional state just like the one with no node-connecting devices added during the first time interval.

Referring back to FIG. 11, in operation 1130, a simulation of the circuit design is performed to determine, for each set of the plurality of sets of bit values, expected test response bit values at outputs of one or more threshold-comparing convertors and at selected digital signal nodes if the circuit design has the selected digital signal nodes. Each of the one or more threshold-comparing convertors is coupled to or to be coupled to one of one or more selected nodes of the circuit design. Like the threshold-comparing convertors 221, 222 and 223 in FIG. 2, each of the one or more threshold-comparing convertors comprises one or more threshold-comparing sub-convertors, and each of the one or more threshold-comparing sub-convertors is configured to output a bit value at one of outputs of the each of the one or more threshold-comparing convertors based on comparing a voltage value at the one of one or more selected nodes with one preset threshold. If a threshold-comparing convertor comprises only one threshold-comparing sub-convertor, the preset threshold may be set at the midpoint of the voltage range for the selected node. If a threshold-comparing convertor comprises two threshold-comparing sub-convertors, one preset threshold may be set above the midpoint of the voltage range for the selected node and the other preset threshold below it, similar to the thresholds 346 and 347 in FIG. 3D. The one or more threshold-comparing sub-convertors can be implemented using CMOS inverters, logic gates or other devices.

The one or more selected nodes coupled to the one or more threshold-comparing convertors can also be selected based on user specification, circuit topology, or both. As noted previously, a node can be a good candidate for observing test responses if it has impedance low enough that connecting an input of threshold-comparing convertor to it would not affect the circuit's performance. Some examples of such low impedance nodes include outputs of functions and outputs of amplifiers.

To perform simulations of the defect-free circuit design for the plurality of sets of bit values, neither the one or more node-connecting devices nor the one or more threshold-comparing convertors need to be inserted into the circuit design, at least in the early stages of design for test process. Simulating a defect-injected circuit design, which will be discussed in detail later, can identify, in the one or more node-connecting devices, the one or more threshold-comparing convertors, or both, some circuitry unnecessary for defect detection. Accordingly, the node-connecting devices and threshold-comparing convertors eventually inserted into the circuit design may be different from those chosen initially. With various implementations of the disclosed technology, an ideal switch can be added in place of a switching device in a node-connecting device with ‘on’ and ‘off’ resistances similar to that of the replaced switching device. Voltages at the one or more selected nodes for observing test responses can be sampled and then compared to the one or more preset thresholds to determine the expected test response bit values without inserting threshold-comparing convertors into the circuit design. Similar to how sets of bit values are applied to and test response bit values are captured from digital combinational logic, voltages at the one or more selected nodes for observing test responses can be sampled just before each set change in the plurality of sets of bit values.

In the circuit 900, the node 946 and the outputs 947 and 948 are selected as the nodes for observing test responses, and each of the threshold-comparing convertors employed comprises two threshold-comparing sub-convertors like the threshold-comparing convertor 340 in FIG. 3D. FIG. 12 further illustrates expected test response bit values 1230 captured during the nine consecutive time intervals obtained based on the simulation of the circuit 900. The first two rows “adc1H” and “adc1L” of the expected test response bit values 1230 represent bit values at the outputs of the threshold-comparing sub-convertor coupled to the node 946; the next two rows “adc2H” and “adc2L” represent bit values at the outputs of the threshold-comparing sub-convertor coupled to the output 947; and the last two rows “adc3H” and “adc3L” represent bit values at the outputs of the threshold-comparing sub-convertor coupled to the output 948.

Referring back to FIG. 11, the operation 1130 may be performed for all process parameter combinations of interest. Typically, a circuit is designed to pass all its function tests for any combination of process parameters values that is within the manufacturing process's specifications. The circuit design can be first simulated with the typical value for each of the circuit element model process parameter values. Then, the circuit design can be simulated with different combinations of various process parameter values. After the process is finished, indeterminate bits in the expected test response bit values are identified. An indeterminate bit in this operation is a bit that has different values for different combinations of the process parameter values, which can be set to be “X”.

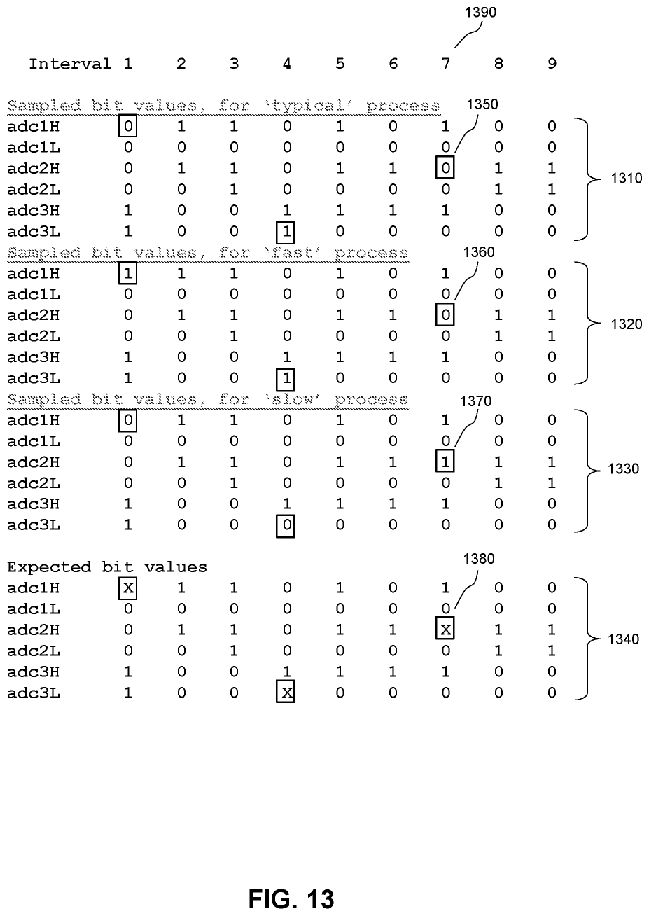

FIG. 13 illustrates an example for determining indeterminate bits in the expected test response bit values for the circuit 900. The simulation of the circuit 900 is performed under a “typical” set of process parameter values, a “worst” or “slow” set of process parameter values, and a “best” or “fast” set of process parameter values, respectively. FIG. 13 lists expected test response bit values 1310, 1320 and 1330 for the three sets of process parameter values captured during the nine consecutive time intervals and final expected test response bit values 1340 derived based on them. By comparing the expected test response bit values 1310, 1320 and 1330, three indeterminate bits are identified and set as “X” in the final expected test response bit values 1340. For example, during the seventh time interval 1390, the test response bits 1350, 1360 and 1370 outputted from the output of the threshold-comparing convertor associated with the node 547 (labeled as “adc2H” in the figure) are “0”, “0”, and “1”, respectively. An “X” is assigned to be the corresponding bit value 1380 in the final expected test response bit values 1340.

In addition to handling explicit process parameter variations, a voltage margin may be added around a preset threshold used by a threshold-comparing sub-convertor to account for additional noise or process variations. If a voltage value at a selected node for observing test responses is within a preset range centered at the preset threshold, the corresponding test response bit value can be set as “X”. For example, if a node's voltage samples range from 1.1 to 1.3 volts for different process parameter values, and the threshold voltage is 1.0 volts, and the added margin is 0.2 volts, then the expected logic value for that sample can be set to ‘X’ because 1.1 is within the 0.2 volt margin around 1.0 volts.

The result of the operations 1110-1130 of the flow chart 1100 In FIG. 11 is a time sequence of test patterns (the plurality sets of bit values) and their expected test response bit values. In operation 1140, defects are injected into the circuit design. Two common types of defects for analog or mixed-signal circuits are open defects and short defects. The latter are also referred to as bridge defects. The defect injection sites can be determined based on user specification, circuit topology, or both. According to various embodiments of the disclosed technology, the defects can be injected into the circuit design one at a time for simulation.

In operation 1150, the operations 1110-1130 are repeated for the defect-injected circuit design. The same pre-determined DC voltage values used in the operation 1110 are applied to the analog inputs of the defect-injected circuit design if the circuit design has the analog inputs. The same plurality of sets of bit values used in the operation 1120 are applied to the inputs of the one or more node-connecting devices coupled to or to be coupled to the one or more selected internal nodes, to the one or more selected digital inputs, or both. Here, the plurality of sets of bit values are applied not only as one set during each of the plurality of consecutive time intervals but also in the same sequence as they are applied to the defect-free circuit design. Simulations of the defects-injected circuit design are then performed to determine a set of test patterns that can detect at least some of the defects. For each of the simulations, test response bit values derived are compared with the corresponding expected test response bit values derived from simulating the defect-free circuit design. If the expected test response bit value is ‘X’, the comparison is not performed. If at least one of the test response bit values is different from the corresponding expected test response bit value, the injected defect(s) can be declared detected. Defect coverage that measures the number of defects detectable by the set of test patterns vs the total number of defects can be determined. If the determined defect coverage is not high enough, the plurality of sets of bit values, the selected internal nodes for test stimuli injection, the selected nodes for test response observation, or any combination thereof may be adjusted.

The set of test patterns may be obtained by selecting all sets of bit values that detect defects not detected by any other set of bit values. The set of test patterns can be compacted without compromising the defect coverage. To choose a minimum number of test patterns, a digital automatic test pattern generation (ATPG) minimization algorithm or a greedy algorithm can be used. According to an example greedy algorithm, every test pattern that is the only pattern to detect a defect is selected. Another test pattern that detects the most of the remaining defects is then selected. If there are any defects left, still another test pattern that detects the most of the current remaining defects is selected, which is repeated until the selected test patterns can detect all of the defects detected by the original set of test patterns.

Sometimes a short sequence of consecutive test patterns may need to be retained even if only the last test pattern in the short sequence detects the defects. This is due to dependency on previous values for the last test pattern. Without using the short sequences of consecutive test patterns, test consistency between the original set of test patterns and the reduced set of test patterns can suffer. Retaining short sequences can also allow the time interval between consecutive test patterns to be reduced so that some signals intentionally do not have time to settle and the sampled node voltages become sensitive to the values of resistances and capacitances. In many types of analog circuits, such as switched-capacitor filters, settling times and signal propagation delays are longer than the period of the highest frequency clock applied to the circuit. Also, some transistors might not conduct any current during some applied test patterns which will cause some node voltages to drift up or down due to leakage current, and this will make the output voltages for the immediately following combination of logic values depend on the preceding combination.

A short sequence of test patterns can be two, three, or more consecutive test patterns. In any case, the expected logic values for all but the last test pattern in each selected short sequence can be set to ‘X’ because the test pattern might be preceded by different test patterns in the reduced set of test patterns than in the original set of test patterns.

Referring back to FIG. 11, in operation 1160, testing circuitry not uniquely contributing to detecting the defects is removed. If a bit value that controls a switching device in a node-connecting device is always the same value that does not enable the switching device, then the switching device can be removed since it does not uniquely contribute to detecting any defect. If a threshold-comparing sub-convertor in a threshold-comparing convertor outputs a bit value that does not uniquely contribute to detecting any defect, then the threshold-comparing sub-convertor can be removed. This operation may be performed after the reduced set of test patterns are obtained, which may lead to more testing circuitry being removed than based on the original set of the test patterns.

In some cases, some or all of the switching devices in node-connecting devices that are not needed to achieve maximum defect coverage may not be removed because they could be deemed useful for diagnosing defects. Similarly, some or all of the threshold-comparing sub-convertors in threshold-comparing convertors that are not needed to achieve maximum defect coverage may not be removed because they could be deemed useful for diagnosing defects.

FIG. 14A illustrates an example defect detection matrix for nine defects of the circuit 900 detected using nine sets of bit values (test patterns) applied during the nine consecutive time intervals. Each row indicates a result for a different defect. The letter “D” indicates the defect of interest is detected. Based on the greedy algorithm, the test pattern applied during the time interval 1430 is selected first because it is the only pattern to detect defect3. The test pattern applied during the time interval 1410 is the one that detects the most of the remaining defects and is thus selected second. The test pattern applied during the time interval 1420 detects the remaining defects and is selected third and also last. A reduced set of the three test patterns applied during the time intervals 1410, 1420 and 1430 is formed. The detect coverage is not impacted.

FIG. 14B illustrates an example of forming a reduced set of short sequences of test patterns. If short sequences of two test patterns are needed to keep test consistency, for example, the test patterns immediately preceding those applied during the time intervals 3 and 6 will be retained, forming two short sequences 1450 and 1460. Since the time interval 1 is the first time interval and has no preceding time interval other than the initial conditions of indefinite duration, its short sequence 1440 contains only one test pattern.

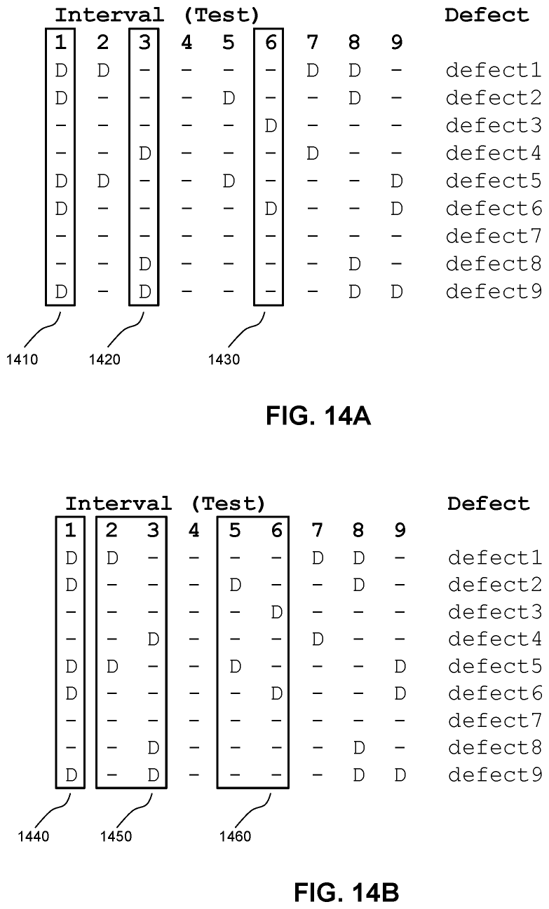

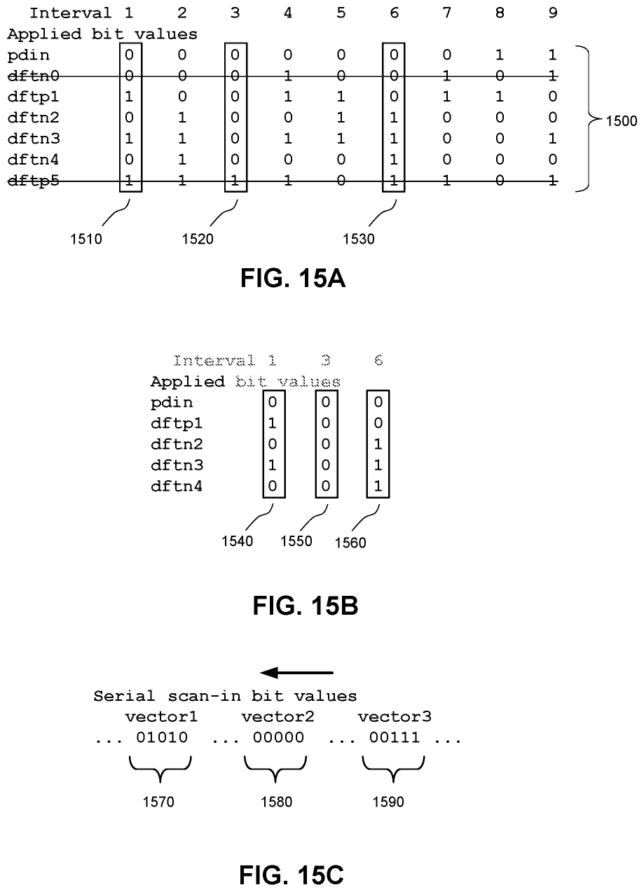

FIG. 15A shows a set of test patterns 1500 applied to the circuit 900 during all of the nine consecutive time intervals. Three test patterns 1510, 1520, and 1530 outlined correspond to the test patterns applied during the time intervals 1410, 1420 and 1430 identified to be associated with the reduced set of test patterns in FIG. 14A. When only this reduced set of test patterns 1510, 1520, and 1530 is considered, the NMOS transistor (dftn0) is driven always by a signal of “0” while the PMOS transistor (dftp5) is driven always by a signal of “1”. As such, they are never enabled and these rows of the set of test patterns 1500 can be crossed out and the NMOS transistor (dftn0) and the PMOS transistor (dftp5) can be removed without affecting the test coverage. FIG. 15B illustrates a reduced set of test patterns 1540, 1550, and 1560, for time intervals 1, 3 and 6, and without the rows for the NMOS transistor (dftn0) and the PMOS transistor (dftp5). FIG. 15C shows how the test patterns 1540, 1550, and 1560 might be shifted in as 1570, 1580, and 1590, respectively, in a serial bit stream applied to a scan chain.

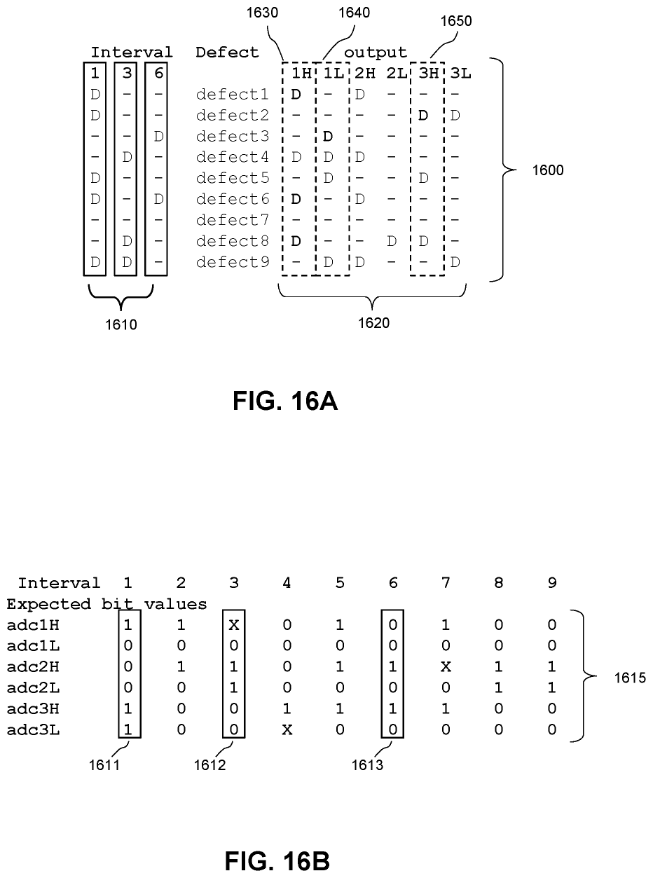

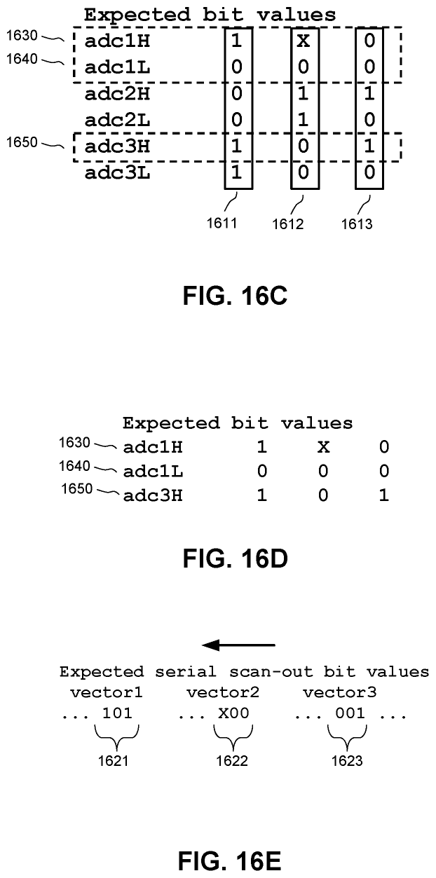

FIG. 16A illustrates an example defect detection matrix 1600 for the circuit 900 in terms of both the reduced set of test pattern bit locations 1610 (corresponding to the time intervals 1410, 1420 1430 of the defect detection matrix in FIG. 14A) and test response bit locations 1620. As noted previously, each of the three threshold-comparing convertors has two threshold-comparing sub-convertors, one using a high threshold (“H”) and the other using a low threshold (“L”), and thus can output two bit values. The threshold-comparing sub-convertors 1630, 1640 and 1650 can be selected, and the rest of the threshold-comparing sub-convertors can be removed since they do not detect defects uniquely. FIG. 16B shows an example of expected test response bit values for each of the threshold-comparing sub-convertors for the nine consecutive time intervals with the reduced set of test patterns in intervals 1, 3, and 6 outlined as 1611, 1612, and 1613. FIG. 16C shows the expected test response bit values only for the time intervals 1611, 1612 and 1613 associated with the reduced set of test patterns. FIG. 16D shows the minimized set of expected test response bit values only for the threshold-comparing sub-convertors 1630, 1640 and 1650. FIG. 16E shows how the minimized set of expected test response bit values might be shifted out as 1621, 1622, and 1623 along a scan chain.

FIG. 17 illustrates an example of test circuitry 1700 for the circuit 900. The test circuitry 1700 comprises a scan chain 1710 and associated update register 1720. The test circuitry 1700 also comprises three node-connecting devices 1730, 1740 and 1750 with inputs coupled to the update register 1720 and outputs coupled to the three selected internal nodes of the circuit 900 and their associated nodes. Here the node-connecting devices 1730 and 1750 have only one switching device due to the reduction of test circuitry as illustrated in FIGS. 17A and 17B. The test circuitry 1700 further comprises two threshold-comparing convertors 1760 and 1770 for observing test responses at the two selected nodes 1781 (X1.int) and 1782 (pout2). According to FIG. 16A-D, neither test responses at another originally selected node 947 (pout) in the circuit 900 nor the low-threshold test response bits for the node 1782 detects defects uniquely. Therefore, there is no threshold-comparing convertor for the originally selected node 947 (pout) and the threshold-comparing convertor 1770 has only one threshold-comparing sub-convertor using a high threshold.

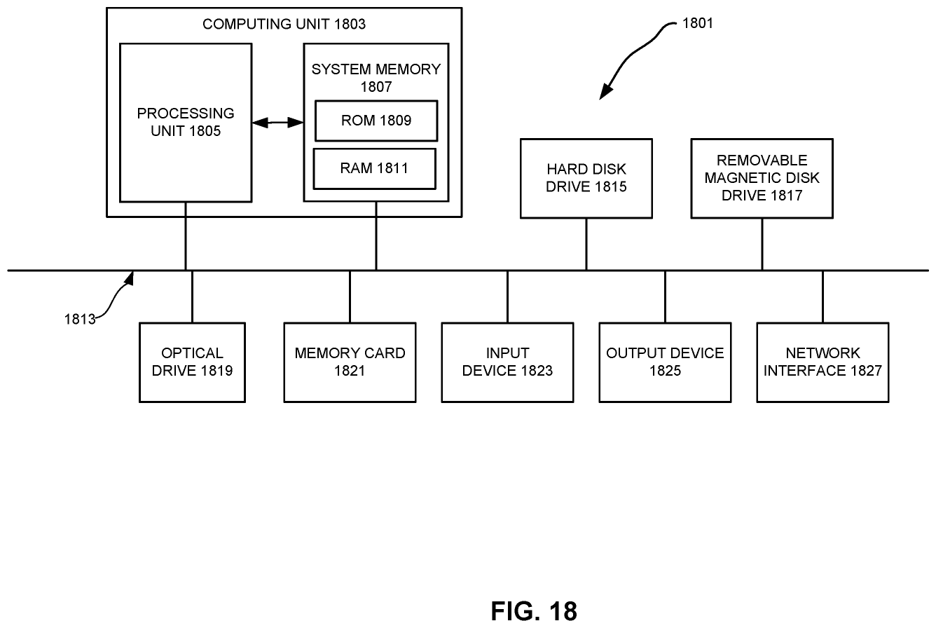

Various examples of the disclosed technology may be implemented through the execution of software instructions by a computing device, such as a programmable computer. Accordingly, FIG. 18 shows an illustrative example of a computing device 1801. As seen in this figure, the computing device 1801 includes a computing unit 1803 with a processing unit 1805 and a system memory 1807. The processing unit 1805 may be any type of programmable electronic device for executing software instructions, but it will conventionally be a microprocessor. The system memory 1807 may include both a read-only memory (ROM) 1809 and a random access memory (RAM) 1811. As will be appreciated by those of ordinary skill in the art, both the read-only memory (ROM) 1809 and the random access memory (RAM) 1811 may store software instructions for execution by the processing unit 1805.

The processing unit 1805 and the system memory 1807 are connected, either directly or indirectly, through a bus 1813 or alternate communication structure, to one or more peripheral devices. For example, the processing unit 1805 or the system memory 1807 may be directly or indirectly connected to one or more additional memory storage devices, such as a “hard” magnetic disk drive 1815, a removable magnetic disk drive 1817, an optical disk drive 1819, or a flash memory card 1821. The processing unit 1805 and the system memory 1807 also may be directly or indirectly connected to one or more input devices 1823 and one or more output devices 1825. The input devices 1823 may include, for example, a keyboard, a pointing device (such as a mouse, touchpad, stylus, trackball, or joystick), a scanner, a camera, and a microphone. The output devices 1825 may include, for example, a monitor display, a printer and speakers. With various examples of the computing device 1801, one or more of the peripheral devices 1815-1825 may be internally housed with the computing unit 1803. Alternately, one or more of the peripheral devices 1815-1825 may be external to the housing for the computing unit 1803 and connected to the bus 1813 through, for example, a Universal Serial Bus (USB) connection.

With some implementations, the computing unit 1803 may be directly or indirectly connected to one or more network interfaces 1827 for communicating with other devices making up a network. The network interface 1827 translates data and control signals from the computing unit 1803 into network messages according to one or more communication protocols, such as the transmission control protocol (TCP) and the Internet protocol (IP). Also, the network interface 1827 may employ any suitable connection agent (or combination of agents) for connecting to a network, including, for example, a wireless transceiver, a modem, or an Ethernet connection. Such network interfaces and protocols are well known in the art, and thus will not be discussed here in more detail.

It should be appreciated that the computing device 1801 is illustrated as an example only, and it is not intended to be limiting. Various embodiments of the disclosed technology may be implemented using one or more computing devices that include the components of the computing device 1801 illustrated in FIG. 18, which include only a subset of the components illustrated in FIG. 18, or which include an alternate combination of components, including components that are not shown in FIG. 18. For example, various embodiments of the disclosed technology may be implemented using a multi-processor computer, a plurality of single and/or multiprocessor computers arranged into a network, or some combination of both.

### CONCLUSION

Having illustrated and described the principles of the disclosed technology, it will be apparent to those skilled in the art that the disclosed embodiments can be modified in arrangement and detail without departing from such principles. In view of the many possible embodiments to which the principles of the disclosed technologies can be applied, it should be recognized that the illustrated embodiments are only preferred examples of the technologies and should not be taken as limiting the scope of the disclosed technology. Rather, the scope of the disclosed technology is defined by the following claims and their equivalents. We therefore claim as our disclosed technology all that comes within the scope and spirit of these claims.

1. A test circuit configured to test a circuit being at least partially analog, comprising:
one or more scan chains configured to shift test patterns generated for structural testing of the circuit into the circuit one at a time, to apply each of the test patterns to the circuit separately, and to capture a test response of the circuit for each of the test patterns; and
one or more threshold-comparing convertors,
wherein each of the one or more threshold-comparing convertors, comprising one or more threshold-comparing sub-convertors for one or more preset thresholds, is coupled to a selected node of the circuit, and
wherein each of the one or more threshold-comparing sub-convertors is configured to output, based on comparing a voltage value at the selected node with one of the one or more preset thresholds, a bit value of the test response to a scan cell of the one or more scan chains.

2. The test circuit recited in claim 1, further comprising:
one or more node-connecting devices with inputs coupled to the one or more scan chains and with outputs coupled to one or more selected internal nodes of the circuit,
wherein each of the one or more node-connecting devices is configured to receive an N-bit signal (N being 1, 2, or 3) directly or indirectly from N scan cells of the one or more scan chains and to at least cause, based on the N-bit signal, one of the one or more selected internal nodes to be either coupled to or decoupled from another node of the circuit.

3. The test circuit recited in claim 2, wherein the each of the one or more node-connecting devices comprises a switching device configured to couple or decouple the internal node to or from the one of two other nodes based on the N-bit signal.

4. The test circuit recited in claim 3, wherein the switching device is a transistor.

5. The test circuit recited in claim 2, wherein the one or more selected nodes are selected based at least on user specification, circuit topology, simulation of the circuit and the circuit injected with defects, or any combination thereof.

6. The test circuit recited in claim 2, wherein N is 1 or 2 and each of at least some of the one or more node-connecting devices is configured to cause, based on a 2-bit signal, a selected internal node to be coupled to either or neither of two other nodes of the circuit.

7. The test circuit recited in claim 6, wherein the each of at least some of the one or more node-connecting devices comprises circuitry configured to prevent the selected internal node from being connected to the two other nodes simultaneously.

8. The test circuit recited in claim 1, wherein each of the one or more threshold-comparing sub-convertors is an inverter formed by two transistors.

9. The test circuit recited in claim 1, wherein each of the one or more threshold-comparing sub-convertors is a multiplexer which a scan cell also uses to select either a parallel input or a serial input.

10. The test circuit recited in claim 1, wherein the selected node is selected based at least on user specification, circuit topology, simulation of the circuit and the circuit injected with defects, or any combination thereof.

11. The test circuit recited in claim 1, wherein the test patterns are generated based on random combinations of bit values or all combinations of bit values.

12. The test circuit recited in claim 1, wherein each of the one or more threshold-comparing convertors comprises at most four threshold-comparing sub-convertors.

13. The test circuit recited in claim 1, further comprising:
update register elements coupled to parallel outputs of the one or more scan chains.

14. The test circuit recited in claim 1, wherein the bit value of the test response is treated as being indeterminate if the voltage value at the selected node is within a preset range centered at the one of the one or more preset thresholds.

15. The test circuit recited in claim 1, wherein the bit value of the test response is treated as being indeterminate if the bit value obtained by simulating the circuit for one combination of process parameter values is not the same as the bit value obtained by simulating the circuit for a different combination of process parameter values.

16. (canceled)
